(19) United States
(12) Patent Application Publication
(10) Pub. No.: US 2013/0270901 A1
(43) Pub. Date: Oct. 17, 2013

(54) Method and Arrangement for Diagnosing Drivers of Contactors, Battery, and Motor Vehicle having such a Battery

(71) Applicants: ROBERT BOSCH GMBH, Stuttgart (DE); SAMSUNG SDI CO., LTD., Yongin-si (KR)

(72) Inventors: Jan Salziger, Esslingen (DE); Michael Rueger, Stuttgart (DE)

(73) Assignees: Samsung SDI Co., Ltd., Yongin-si (KR); Robert Bosch GmbH, Stuttgart (DE)

(21) Appl. No.: 13/860,917

(22) Filed: Apr. 11, 2013

(30) Foreign Application Priority Data
Apr. 12, 2012 (DE) 10 2012 206 007.3

(51) Int. Cl. G01R 31/00; B60L 3/04; G01R 31/02

(52) U.S. Cl. CPC G01R 31/007; G01R 31/02; B60L 3/04
USPC 307/9.1; 324/418

(57) ABSTRACT

The disclosure relates to a method and an arrangement for diagnosing drivers of contactors, to a battery, and to a motor vehicle having such a battery. According to the method, information relating to switching states of at least three drivers of a contactor is stored, with information relating to respective associated desired values of at least one predefinable parameter, in a computer-readable memory. Actual switching states of at least some of the drivers are detected with associated actual values and are compared with the stored desired values in order to diagnose the drivers. A fault is diagnosed if at least one actual value differs from a desired value.

This application claims priority under 37 U.S.C. §119 to patent application no. DE 10 2012 206 007.3, filed on Apr. 12, 2012 in Germany, the disclosure of which is incorporated herein by reference in its entirety.

### BACKGROUND

The present disclosure relates to a method and an arrangement for diagnosing drivers of contactors, to a battery, and to a motor vehicle having such a battery, which can be used, in particular, for simplified diagnosis of drivers of a contactor.

In hybrid and electric vehicles, battery packs are isolated from the other components, such as the drive, additional generator, charging plug etc., by power contactors. Safe disconnection of these contactors is required under all circumstances on account of the high voltages and currents. In addition, a contactor must be prevented from being connected in an uncontrolled manner.

In systems having such safety requirements, a contactor 100 is generally driven by two independent drivers 102, 104 (cf. FIG. 1). The first driver 102 generally switches the positive supply voltage 106 to the contactor 100, and the second driver 104 connects the negative side of the contactor 100 to the negative potential 108 of the supply voltage. Switching of the drivers 102, 104 is initiated by driver controllers 110, 112.

Disconnection can therefore be effected by one of the drivers 102, 104. Connection through the contactor 100 is possible only when both drivers 102, 104 have been activated.

In the case of large contactors 202, use is made of a circuit 200 which enables a reduced flow of current through the contactor 202 after the contactor 202 has been closed. This reduces the power consumption, thus preventing overheating and destruction of the contactor 202.

This circuit 200 may be designed differently. In the simplest form, it consists of a second voltage source 204 which can be connected by means of a third driver 206 under the control of a driver controller 208 (cf. FIG. 2).

Irrespective of the safety classification, it is necessary to diagnose drivers. A simple driver circuit with an associated diagnostic circuit is illustrated in FIG. 3.

A correct function of the driver (here the driver 104 on the negative side) and the cabling to the connected contactor 100 can be checked by measuring the voltage on the diagnostic line 302.

Conventional drivers are available with an integrated diagnostic option. They may be directly used in circuits according to FIG. 3. They diagnose load chopping, for example, by virtue of the fact that the voltage on the diagnostic line 302 does not fall when the driver 104 is driven.

In a circuit according to FIG. 2, the following diagnoses are possible (cf. FIG. 4):

A load chopping 402 at the negative terminal,

B short circuit 404 to ground at the negative terminal,

C short circuit 406 to the supply voltage at the negative terminal,

D load chopping 408 at the positive terminal,

E short circuit 410 to ground at the positive terminal,

F short circuit 412 to the supply voltage at the positive terminal.

The driver-internal diagnosis cannot be used in a circuit according to FIG. 2 since it would diagnose load chopping 402, for example, when the second driver 104 is open.

In circuits having two drivers, a diagnostic circuit can be designed in the manner represented in FIG. 5. The voltages on the diagnostic lines 112, 502 are dependent on the state of the two drivers 102, 104 and the levels of the diagnostic voltage 504 U_Diag and the holding voltage 204 U_Hold. Driver-internal diagnosis is no longer possible here.

In order to diagnose faults, the value of the diagnostic circuit must be evaluated in particular switching states. For this purpose, the controlling software must be synchronized with the diagnosing software in a complicated manner.

### SUMMARY

A particular advantage of the disclosure is that it is no longer necessary to synchronize controlling software with the diagnosing software. This is achieved by virtue of the fact that, in the method according to the disclosure for diagnosing drivers of a contactor, information relating to at least some switching states of drivers of the contactor and information relating to the desired values of predefinable parameters corresponding to the switching states is stored in a computer-readable storage medium. The information is preferably stored in tables. One preferred embodiment provides for the information to comprise at least information relating to desired voltages or bit masks. The bit masks may be output, for example, by diagnostic systems integrated in one or more driver modules. In order to diagnose the drivers, the current switching states of the drivers, that is to say the switching states of the drivers at the time of diagnosis, that is to say the actual switching states, and the associated actual values, for example actual voltages, are detected and are compared with the information stored in the memory. If it is determined, during the comparison, that one or more actual values differ from the desired values, a fault is diagnosed. The stored information is preferably some switching states, preferably all switching states, of the three drivers and the values of the voltages to be evaluated for diagnosis.

One preferred embodiment provides for information relating to the type of faults to be stored in the memory in addition to the information relating to the switching states and the desired values. This information may be, for example, statements such as: load chopping at the positive or negative terminal of the contactor, short circuit to ground at the positive or negative terminal of the contactor, short circuit to the supply voltage at the positive or negative terminal of the contactor or the like.

Another preferred embodiment provides for the positive and/or negative side of the contactor to be diagnosed. The information is preferably stored in two separate tables for the positive and negative sides of the contactor. In this case, provision may be made for the positive and negative sides of the contactor to be diagnosed independently of one another.

Another preferred embodiment provides for at least some of the actual values, for example the actual voltages, and/or one or more bit masks to be evaluated in order to determine the type of fault. The type of fault is determined on the basis of the actual values. For example, load chopping or a short circuit to the supply voltage at the positive terminal of the contactor may be diagnosed on the basis of a measured actual voltage value.

An arrangement according to the disclosure comprises at least one contactor, three drivers, a memory means and a data processing unit. According to the disclosure, the arrangement is also set up such that a method for diagnosing drivers of contactors can be carried out, information relating to switching states of at least three drivers of a contactor being stored, with respective associated desired values of at least one predefinable parameter, in a computer-readable memory, and actual switching states of at least some of the drivers (102, 104, 206) being detected with associated actual values and being compared with the stored desired values in order to diagnose the drivers (102, 104, 206), and a fault being diagnosed if at least one actual value differs from a desired value.

In one preferred embodiment, the arrangement comprises a circuit which connects the contactor to the positive potential of a supply voltage U_BATT, preferably to a battery, via a first driver.

For this purpose, a terminal on the positive side of the contactor is connected to a terminal of the first driver via an electrically conductive connection. The second terminal of the first driver is connected to the positive potential of the supply voltage U_BATT. Via a second connection, the terminal on the negative side of the contactor is connected to a terminal of the third driver via an electrically conductive connection. A second terminal of the third driver is connected to the negative potential of the supply voltage U_BATT. In addition, the terminal on the positive side of the contactor is electrically connected to a terminal of the second driver. The contactor can be connected to the source of a holding voltage U_HOLD via the second driver.

Another preferred embodiment provides for a first actual voltage to be tapped off at the connection on the positive side of the contactor between the contactor and the first driver. For this purpose, a first diagnostic line is connected to the electrically conductive connection between the contactor and the first driver. The first diagnostic line between the first driver and the terminal of the second driver is preferably connected to the connection between the contactor and the first driver at the electrically conductive connection between the contactor and the first driver. The actual voltages for diagnosing the positive side of the contactor are detected on the first diagnostic line.

Another preferred embodiment provides for a second diagnostic line to be connected to the electrically conductive connection between the contactor and the third driver. The actual voltages for diagnosing the negative side of the contactor are detected on the second diagnostic line.

Another preferred embodiment provides for the first diagnostic line to be connected to the positive side of the contactor via a resistance network.

Another preferred embodiment provides for a diagnostic voltage U_DIAG to be applied to the circuit. For this purpose, a source of the diagnostic voltage U_DIAG is connected to the positive side of the contactor. The source of the diagnostic voltage U_DIAG between the first driver and the terminal of the second driver is preferably connected to the connection between the contactor and the first driver at the electrically conductive connection between the contactor and the first driver. It proves to be advantageous if the source of the diagnostic voltage U_DIAG is connected to the positive side of the contactor via a resistor.

The diagnostic voltage U_DIAG, the holding voltage U_HOLD, the positive supply voltage U_BATT and the resistors are designed in this case in such a manner that as many types of fault as possible can be diagnosed using the actual voltage measured on the first diagnostic line. In one preferred embodiment, a supply voltage U_BATT=12 V and a diagnostic voltage U_DIAG=5 V are provided, for example.

Another aspect of the disclosure relates to a battery which is combined with an arrangement, the arrangement having at least one contactor, three drivers, a data processing unit and memory means, and the arrangement being set up in such a manner that a method for diagnosing drivers of contactors can be carried out, information relating to switching states of at least three drivers of a contactor being stored, with respective associated desired values of at least one predefinable parameter, in a computer-readable memory, and actual switching states of at least some of the drivers (102, 104, 206) being detected with associated actual values and being compared with the stored desired values in order to diagnose the drivers (102, 104, 206), and a fault being diagnosed if at least one actual value differs from a desired value. The battery is preferably a lithium ion battery or the battery comprises electrochemical cells in the form of lithium ion battery cells. In this case, a plurality of lithium ion battery cells can be combined to form one electrochemical module.

Another aspect of the disclosure relates to a motor vehicle having an electrical drive motor for driving the motor vehicle and a battery according to the aspect of the disclosure described in the preceding paragraph which is connected or can be connected to the electrical drive motor. However, the battery is not restricted to such an intended purpose, but rather may also be used in other electrical systems.

According to the disclosure, all possible switching states of the drivers with the associated voltages (actual voltages) applied to the diagnostic lines are therefore reproduced in a table. A diagnostic driver checks the voltages applied to the diagnostic lines according to the actually set switching state (actual switching state). If the measured actual voltages do not match the voltage values associated with the actual switching state, there is a fault. Complicated synchronization of the controlling and diagnosing software is dispensed with when using the disclosure.

### BRIEF DESCRIPTION OF THE DRAWINGS

Exemplary embodiments of the disclosure are explained in more detail using the drawings and the following description. In the drawings:

FIG. 1 shows an exemplary circuit diagram of a contactor having two drivers,

FIG. 2 shows an exemplary circuit diagram of a contactor having two drivers and a voltage source which can be connected via a third driver,

FIG. 3 shows an illustration of a simple driver circuit with a diagnostic circuit,

FIG. 4 shows an illustration of possible faults in a driver circuit,

FIG. 5 shows an illustration of a diagnostic circuit for a circuit having two drivers,

FIG. 6 shows a flowchart of exemplary driver diagnosis,

FIG. 7 illustrates Table 1, which shows the switching states of three drivers, and

FIG. 8 illustrates Table 2, which shows the switching states of three drivers.

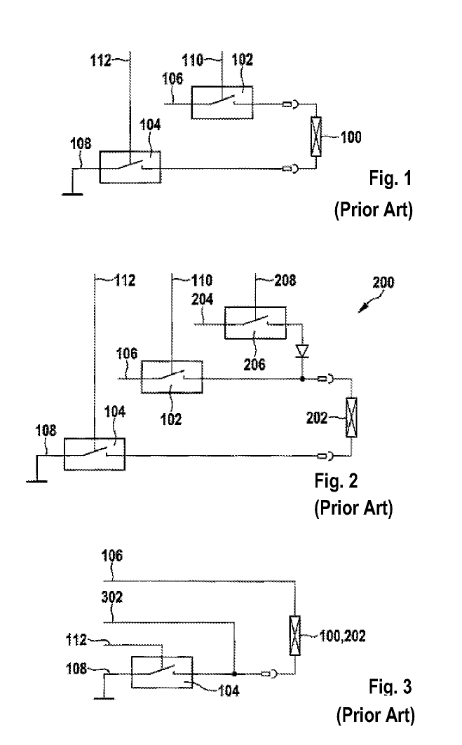

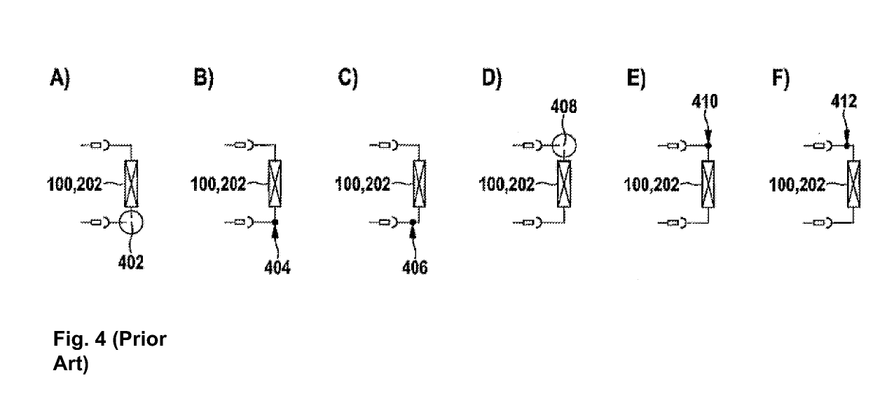

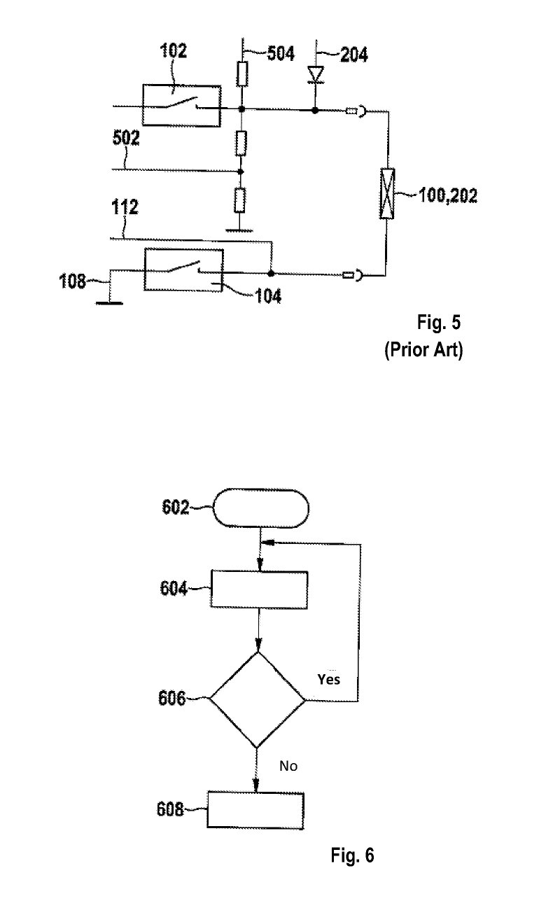

### DETAILED DESCRIPTION

FIG. 6 illustrates the sequence of exemplary driver diagnosis. In this case, the driver diagnosis starts in step 602. In step 604, the actual switching states of the drivers 102, 104, 206 and the actual voltages associated with the actual switching states are detected. The detected actual voltages are compared with the stored desired voltages associated with the detected actual switching states in step 606. If the comparison reveals that the actual voltages measured in step 604 correspond to the stored desired voltages associated with the detected actual switching states within predefinable fault tolerances, the process returns to the beginning and the detection of actual switching states and actual voltages is repeated in step 604. One preferred embodiment provides for the detection to be repeated at intervals of 5 ms. If the comparison in step 606 reveals that the actual voltages measured in step 604 differ from the stored desired voltages associated with the detected actual switching states by more than a permissible amount, a corresponding fault message is output in step 608.

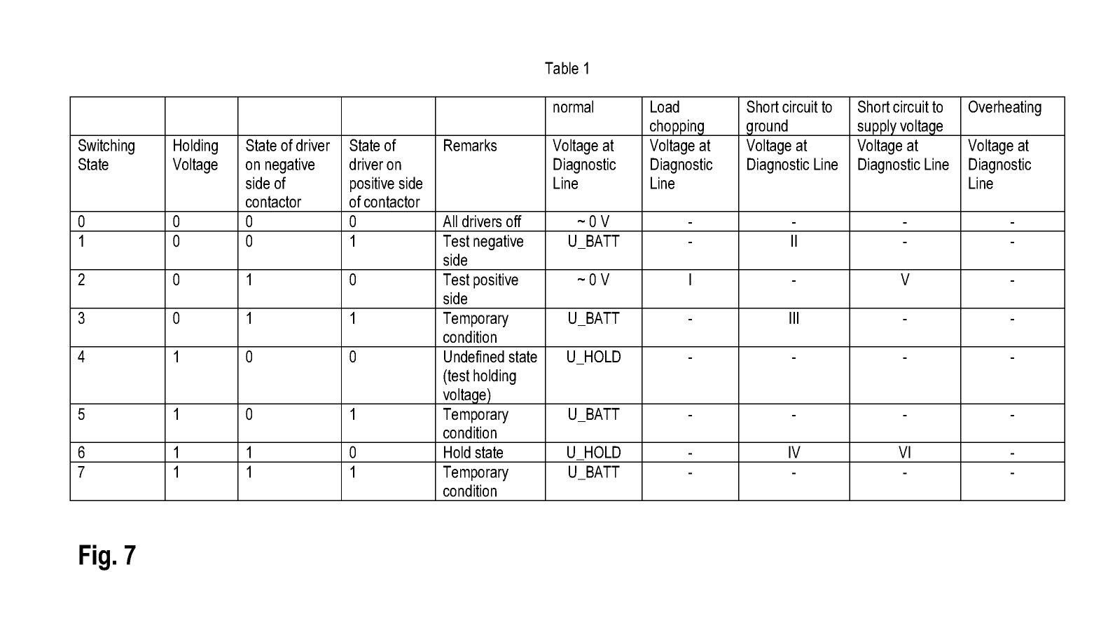

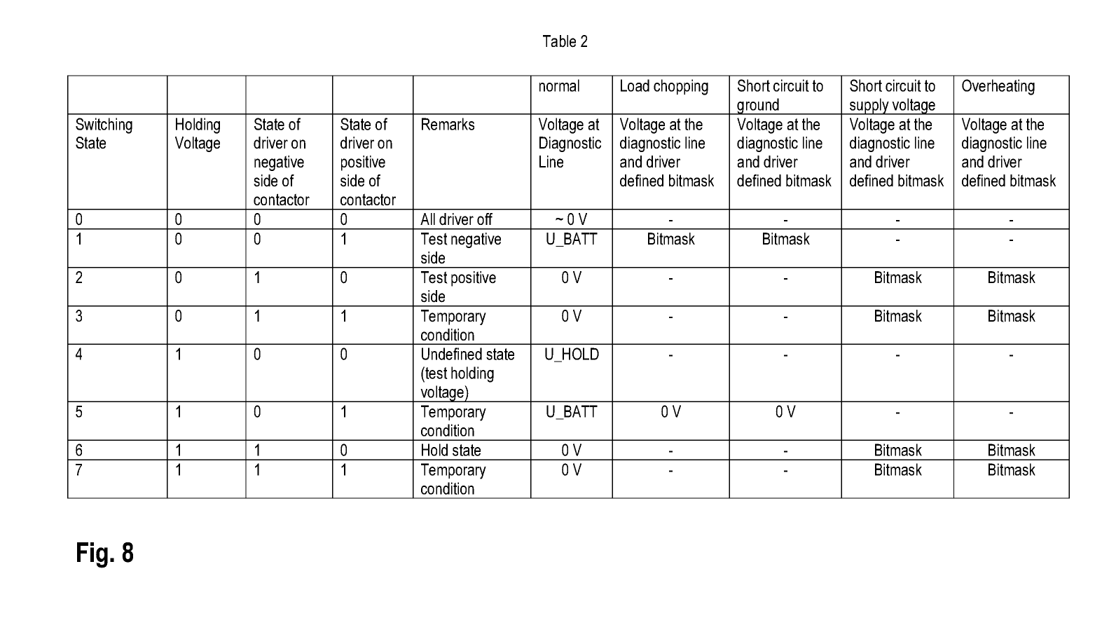

All eight switching states of three drivers 102, 104, 206 of a contactor 100, 202 are entered in Tables 1 and 2, as shown in FIGS. 7 and 8 respectively. In Column 1 of Tables 1 and 2, the switching states are labeled states 0 to 7. Column 2 of Tables 1 and 2 indicates the switching states of the driver 206 which connects the holding voltage of the driver circuit, Column 3 of Tables 1 and 2 indicates the switching states of the driver 104 on the negative side of the contactor 100, 202, and Column 4 of Tables 1 and 2 indicates the switching states of the driver 102 on the positive side of the contactor 100, 202.

Table 1 shows the switching states of the three drivers 102, 104, 206, the associated desired voltages on the diagnostic line 502 on the positive side of the contactor 100, 202 and the types of faults which can be detected if the actual voltage which is measured on the diagnostic line 502 on the positive side of the contactor 100, 202 differs from the desired voltages entered in Column 6 of Table 1 as being associated with the desired switching state.

The desired voltages which are intended to be applied to the diagnostic line 502 on the positive side of the contactor 100, 202 during fault-free operation of the drivers are entered in Column 6 of Table 1.

Column 7 of Table 1 indicates the circumstances under which load chopping 408 at the positive terminal of the contactor 100, 202 can be diagnosed. This is the case (case I) when the driver 104 on the negative side of the contactor 100, 202 is switched on, but the other drivers 102, 206 are switched off. In this case, load chopping 408 at the positive terminal of the contactor 100, 202 is detected if the voltage measured on the diagnostic line 502 on the positive side of the contactor 100, 202 is in a specified range which depends on the specific hardware configuration and the contactor used. For the other switching states, load chopping 408 at the positive terminal of the contactor 100, 202 cannot be diagnosed in the event of a fault (indicated by ‘-’ in the tables).

Column 8 of Table 1 indicates the circumstances under which a short circuit 410 to ground at the positive terminal of the contactor 100, 202 can be diagnosed. This is the case (case I) once when the driver 102 on the positive side of the contactor 100, 202 is switched on, but the other drivers 104, 206 are switched off. In this case (case II), a short circuit 410 to ground at the positive terminal of the contactor 100, 202 is detected if the voltage measured on the diagnostic line 502 on the positive side of the contactor 100, 202 assumes a value which is less than a defined first threshold. This threshold is dependent on the components used and can be configured for each type of contactor. A short circuit 410 to ground at the positive terminal of the contactor 100, 202 can also be diagnosed for the switching state in which the drivers 102, 104 on the positive and negative sides are switched on and the driver 206 for the holding voltage is switched off (case III). For this switching state, a short circuit 410 to ground at the positive terminal of the contactor 100, 202 can be detected if the voltage measured on the diagnostic line 502 on the positive side of the contactor 100, 202 assumes a value which is less than a defined second threshold. A short circuit 410 to ground at the positive terminal of the contactor 100, 202 can also be detected for switching state 6, that is to say when the driver 104 on the negative side of the contactor 100, 202 is switched off, but the other drivers 102, 206 are switched on (case IV), if the following condition is met: the voltage measured on the diagnostic line 502 on the positive side of the contactor 100, 202 assumes a value which is less than a defined third threshold.

Column 9 of Table 1 indicates the circumstances under which a short circuit 412 to the supply voltage at the positive terminal of the contactor 100, 202 can be diagnosed. This is the case (case V) when the driver 104 on the negative side of the contactor 100, 202 is switched on, but the other drivers 102, 206 are switched off. In this case, a short circuit 412 to the supply voltage at the positive terminal of the contactor 100, 202 is detected if the voltage measured on the diagnostic line 502 on the positive side of the contactor 100, 202 has a value which exceeds at least a defined fourth threshold. A short circuit 412 to the supply voltage at the positive terminal of the contactor 100, 202 can also be detected for switching state 6, that is to say when the driver 104 on the negative side of the contactor 100, 202 is switched off, but the other drivers 102, 206 are switched on (case VI), if the following condition is met: the voltage measured on the diagnostic line 502 on the positive side of the contactor 100, 202 assumes a value which is greater than a defined fifth threshold. Since the values of the thresholds depend on the respective specific hardware configuration, as mentioned, all thresholds may assume different values and at least some of the thresholds may assume the same value.

As shown in Column 10 of Table 1, overheating cannot be diagnosed by measuring the voltage applied to the diagnostic line 502 on the positive side of the contactor 100, 202.

The faults which cannot be diagnosed are indicated by ‘-’ in the table.

Table 2 shows the switching states of the three drivers 102, 104, 206, the associated desired voltages on the diagnostic line 112 on the negative side of the contactor 100, 202 and the types of faults which can be detected if the actual voltage which is measured on the diagnostic line 112 on the negative side of the contactor 100, 202 differs from the desired voltages which are entered in Column 6 of Table 2 as being associated with the desired switching state.

Table 2 has the same structure as Table 1.

When detecting the actual voltages during driver diagnosis, the diagnostic driver, in one exemplary embodiment of the disclosure, generates a bit mask comprising a bit pattern of the measured actual voltage. In the event of a fault, the type of fault can be diagnosed for a number of switching states by evaluating the bit mask.

In order to diagnose the negative side of the contactor 100, 202, load chopping 402 at the negative terminal of the contactor 100, 202 and a short circuit 404 to ground at the negative terminal of the contactor 100, 202 can be diagnosed for switching state 1, that is to say when the driver 102 on the positive side of the contactor 100, 202 is switched on, but the other drivers 104, 206 are switched off, by evaluating the bit mask.

A short circuit 406 to the supply voltage at the negative terminal of the contactor 100, 202 and overheating can be diagnosed for switching states 2, 3, 6 and 7 by evaluating the bit mask.

In the switching state in which the driver 104 on the negative side of the contactor 100, 202 is switched off, but the other drivers 102, 206 are switched on, load chopping 402 at the negative terminal of the contactor 100, 202 or a short circuit 404 to ground at the negative terminal of the contactor 100, 202 can be diagnosed if the voltage measured on the diagnostic line 112 on the negative side of the contactor 100, 202 assumes the value 0 V (which can likewise be gathered from the bit mask).

In order to avoid faults during diagnosis, caused by noise in the communication buses for example, an exemplary embodiment provides for the diagnostic measurement to be repeated when a fault is detected and, after a predefinable number of preferably comparable measurement results which indicate a fault, for the diagnosis of this fault to be validated a fault. One exemplary embodiment provides for the diagnostic measurement to be repeated 3 to 10 times. The number of repetitions depends on the interval of time between the repetitions and/or on the level of safety requirements. One exemplary embodiment provides for diagnostic measurements to be repeated at intervals of 5 ms.

Under certain conditions, it may also be expedient to omit parts of the table if they are not relevant to detecting faults (for example line 4).

The embodiment of the disclosure is not restricted to the preferred exemplary embodiments stated above. Rather, a number of variants which also use the method according to the disclosure, the arrangement according to the disclosure, the battery according to the disclosure and the motor vehicle according to the disclosure in fundamentally different embodiments are conceivable.

What is claimed is:

1. A method for diagnosing drivers of contactors, comprising:
storing information in a computer-readable memory relating to desired switching states of at least three drivers of a contactor, wherein the information relates to respective associated desired values of at least one predefinable parameter;
detecting actual switching states of at least some drivers of the at least three drivers, wherein the actual switching states are associated actual values;
comparing the actual values with the desired values in order to diagnose the drivers; and
diagnosing a fault if at least one actual value differs from a desired value.

2. The method according to claim 1, further comprising:
storing information relating to a type of fault in the computer-readable memory.

3. The method according to claim 1, wherein the diagnosing includes diagnosing at least one of a positive side of the contactor and a negative side of the contactor.

4. The method according to claim 1, wherein the desired values include at least one of (i) a desired voltage and (ii) at least one bit mask.

5. The method according to claim 1, further comprising:
evaluating a diagnostic voltage in order to diagnose the drivers.

6. An arrangement comprising:
a contactor;
at least three drivers associated with the contactor;
a data processing unit; and
a memory device,
wherein the arrangement is configured to perform a method for diagnosing the at least three drivers associated with the contactor,
wherein the method includes
storing information in the memory device relating to desired switching states of the at least three drivers, wherein the information relates to respective associated desired values of at least one predefinable parameter,
detecting actual switching states of at least some drivers of the at least three drivers, wherein the actual switching states are associated actual values, comparing the actual values with the desired values in order to diagnose the drivers, and
diagnosing a fault if at least one actual value differs from a desired value.

7. The arrangement according to claim 6, further comprising:
a circuit;
a positive terminal on a positive side of the contactor, the positive terminal being connected to a first driver of the at least three drivers and to a second driver of the at least three drivers; and
a negative terminal on a negative side of the contactor, the negative terminal being connected to a third driver of the at least three drivers,
wherein the circuit is configured to connect to a source of a holding voltage via the second driver,
wherein the connection between the positive terminal and the first driver is connected to a first diagnostic line, and
wherein the connection between the negative terminal and the third driver is connected to a second diagnostic line in order to detect the actual voltages.

8. The arrangement according to claim 6, wherein the connection between the positive terminal on the positive side of the contactor and the first driver is connected to a source for a diagnostic voltage.

9. The arrangement according to claim 6, further comprising a battery.

10. A motor vehicle comprising:
an electrical drive motor configured to drive the motor vehicle;
a battery configured to be connected to the electrical drive motor; and
an arrangement including (i) a contactor, (ii) at least three drivers associated with the contactor, (iii) a data processing unit, and (iv) a memory device,
wherein the arrangement is configured to perform a method for diagnosing the at least three drivers associated with the contactor,
wherein the method includes
storing information in the memory device relating to desired switching states of the at least three drivers, wherein the information relates to respective associated desired values of at least one predefinable parameter,
detecting actual switching states of at least some drivers of the at least three drivers, wherein the actual switching states are associated actual values,
comparing the actual values with the desired values in order to diagnose the drivers, and
diagnosing a fault if at least one actual value differs from a desired value.
